(19) United States
(12) Patent Application Publication
(10) Pub. No.: US 2024/0145428 A1
(43) Pub. Date: May 2, 2024

(54) FLIP CONNECTION STRUCTURE, ROOM-TEMPERATURE FLIP CONNECTION STRUCTURE, AND CONNECTION METHOD THEREFOR

(71) Applicant: SONY SEMICONDUCTOR SOLUTIONS CORPORATION, KANAGAWA (JP)

(72) Inventors: KAZUHIDE TERAHATA, KUMAMOTO (JP); YUSUKE ANDO, KUMAMOTO (JP); SATORU TANIMOTO, KUMAMOTO (JP)

(21) Appl. No.: 18/549,372

(22) PCT Filed: Mar. 10, 2022
(86) PCT No.: PCT/JP2022/010580

§ 371 Date: Sep. 7, 2023

(30) Foreign Application Priority Data
Mar. 18, 2021 (JP) 2021-045132

(51) Int. Cl. H01L 23/00; H01L 23/14; H10K 59/131

(52) U.S. Cl. CPC H01L 24/81; H01L 23/14; H01L 24/05; H01L 24/11; H01L 24/13; H01L 24/16; H10K 59/131; H01L 2224/05124; H01L 2224/1134; H01L 2224/13124; H01L 2224/16225; H01L 2224/81095; H01L 2224/81205; H01L 2924/15165

(57) ABSTRACT

Provided are a flip connection structure, a room-temperature flip connection structure, and a connection method therefor, in which there is no risk of deterioration of a substrate or a semiconductor chip due to heat. Provided is a flip-chip connection structure in which semiconductors are connected using a flip chip structure of chip on chip. Each of terminals that connects the semiconductors is formed by aluminum (Al), and the terminals constitute a joined body integrally joined to each other by ultrasonic vibration involving pressurization.

### TECHNICAL FIELD

The present disclosure relates to a flip connection structure known as a connection structure of a semiconductor chip or the like, a room-temperature flip connection structure, and a connection method therefor.

### BACKGROUND ART

In recent years, as one of micro connection structures, use of a flip chip as a connection method or a connection structure allowing high density implementation is known. In a case where this flip chip connection is performed, for example, a pad electrode, a bump, and the like of a semiconductor chip or a substrate is connected to a terminal, an electrode, and the like on the other side by flux, solder cream, and the like (see, for example, Patent Document 1).

### CITATION LIST

### Patent Document

Patent Document 1: Japanese Patent Application Laid-Open No. 62-296431

### SUMMARY OF THE INVENTION

### Problems to be Solved by the Invention

However, for such connection, it is necessary to heat and warm the flux or the solder using an apparatus serving as a warming unit. For this reason, there is a risk that problems such as warping of the substrate due to the heat may occur. Furthermore, in a semiconductor chip or the like that is weak against heat, there is a risk of causing deterioration or failure due to heat. In addition, for example, regarding a display such as an organic EL or a liquid crystal, there is also a risk of deterioration due to heat at the time of joining.

In view of such circumstances, it is desired to provide a flip connection structure, a room-temperature flip connection structure, and a connection method therefor, which do not cause a risk of deterioration of a substrate or a semiconductor chip due to heat.

### Solutions to Problems

A first flip connection structure of the present disclosure is a flip-chip connection structure in which semiconductors are connected by a flip chip, the flip-chip connection structure including: terminals that connects the semiconductors, the terminals each being formed by aluminum (Al), the terminals being integrally joined to each other to constitute a joined body.

A second room-temperature flip-chip connection structure of the present disclosure is a connection structure of a flip chip in which a semiconductor is connected to a substrate to be used in a liquid crystal panel or an organic EL panel of a display system, in which the semiconductor is joined and formed to a substrate of at least one of the liquid crystal panel and the organic EL panel at room temperature.

A third flip-chip connection method of the present disclosure is a flip-chip connection method of forming semiconductors by joining the semiconductors to each other by a flip-chip connection method using a joined body by an aluminum bump and an aluminum pad electrode or an aluminum bump and an aluminum bump, the flip-chip connection method including: when joining of a flip chip is performed, joining by weighting or pressurization and an ultrasonic wave in an environment of room temperature in any step.

### BRIEF DESCRIPTION OF DRAWINGS

FIG. 1 is a perspective view illustrating an organic EL display device according to an embodiment of the present disclosure.

FIG. 2 is a cross-sectional view taken along line I-I of the organic EL display device illustrated in FIG. 1.

FIG. 3 is an explanatory view illustrating a manufacturing process of the organic EL display device illustrated in FIG. 1.

FIG. 4 is an explanatory view illustrating a method of forming an aluminum bump on a pad electrode provided on a side of a semiconductor chip (DDIC) illustrated in FIG. 3A.

FIG. 5 is an explanatory view illustrating a method of forming an aluminum bump in a case where the aluminum bump is formed on the pad electrode provided on a substrate of an organic EL device in the manufacturing process of the organic EL device illustrated in FIG. 3.

FIG. 6 is an explanatory view illustrating a state immediately before joining when the pad electrode on the side of the semiconductor chip (DDIC) is joined to the pad electrode provided on a side of the substrate of the organic EL display device according to the embodiment of the present disclosure via an Al bump.

FIG. 7 is an explanatory view illustrating a state when the pad electrode on the side of the semiconductor chip (DDIC) is joined to the pad electrode provided on the side of the substrate of the organic EL display device according to the embodiment of the present disclosure via the Al bump.

FIG. 8 is a schematic explanatory view illustrating a modification of the embodiment of the present disclosure and illustrating a state immediately before joining of main portions.

FIG. 9 is a graph illustrating an experimental result in a comparative experiment for examining a temporal change in a resistance value with respect to a joined body of aluminum (Al) and a joined body of aluminum (Al) and gold (Au) according to the present disclosure.

### MODE FOR CARRYING OUT THE INVENTION

Hereinafter, embodiments, modifications, experimental examples, and the like of the present disclosure will be described in detail with reference to the accompanying drawings.

Note that the following description is a specific example of the present disclosure, and the present disclosure is not limited to the following aspects. In each drawing, three-dimensional Cartesian coordinates orthogonal to each other are added in a right-handed system in order to clarify the viewing direction. In addition, the present disclosure is not limited to the arrangement, dimensions, dimensional ratios, and the like of the components illustrated in each drawing.

The contents according to the present disclosure will be described in the following order.
1. Embodiments (Joining Example of Al Bump and Al Pad Electrode or Al Bump and Al Bump)
2. Modification of Embodiments (Joining Example with Al Pad Electrode and Thick Al Pad Electrode)
3. Experimental Examples (Comparative Experimental Examples Regarding Temporal Change in Resistance Value for Joined Body of Al and Al and Joined Body of Al and Au)
4. Application Examples

### 1. Embodiments

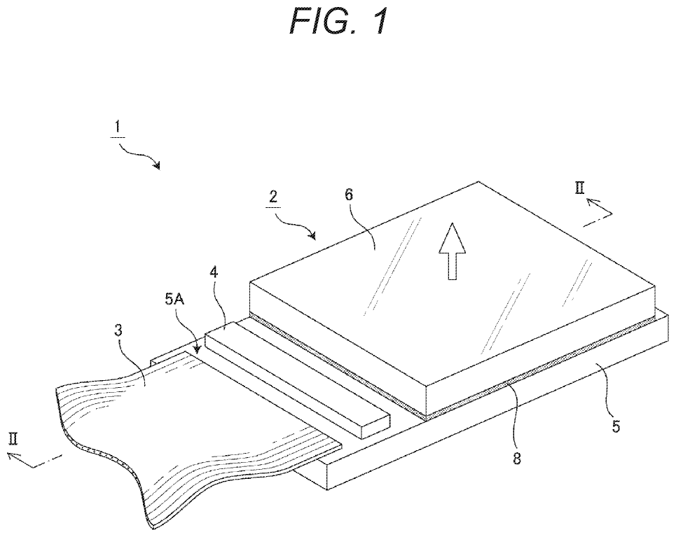

FIG. 1 schematically illustrates a configuration example of a semiconductor device 1 using a joining structure of an aluminum bump (Al-bump) and an aluminum pad electrode according to a first embodiment of the present disclosure. In the semiconductor device 1, an organic EL display device 2 that is easily affected by heat is provided.

### (1-1. Configuration of Semiconductor Device Including Organic EL Display Device and CoC Joining Structure)

### [Configuration of Semiconductor Device]

FIG. 1 illustrates a semiconductor device 1 including an organic EL display device 2 to which a flip connection structure according to a first embodiment of the present disclosure is applied.

The semiconductor device 1 includes the organic EL display device 2 (hereinafter sometimes abbreviated as “ELD 2”), a flexible printed circuit 3 (FPC, hereinafter abbreviated as “FPC3”) that electrically connects an external power supply to the organic EL display device 2 or the like, a display drive IC (DDIC) 4 that drives the organic EL display device 2, and an organic EL display substrate 5 (hereinafter, abbreviated as “substrate 5”) including silicon (Si) or the like that joins and mounts the ELD 2, the FPC 3, the DDIC 4, and the like.

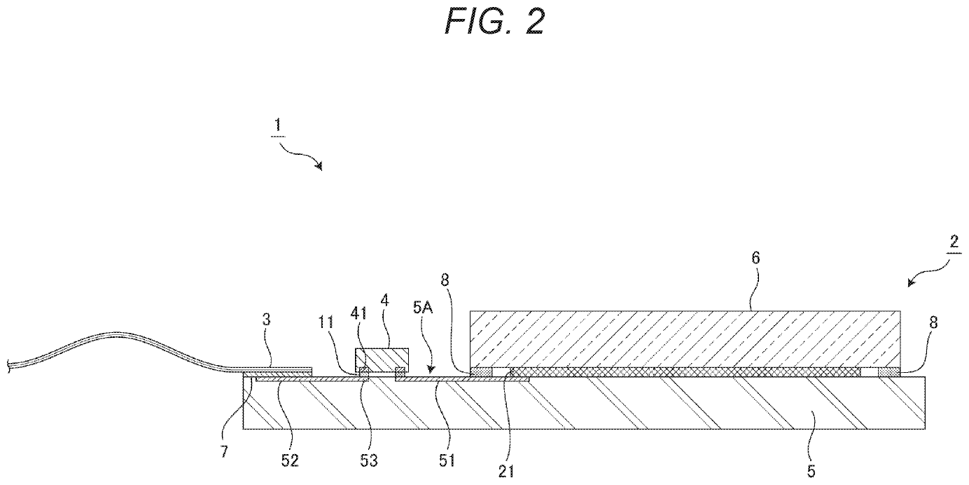

In the organic EL display device 2 (ELD 2), a light emitting element is provided for each pixel, and as is well known, for example, a negative electrode such as metal, an electron injection layer, a light emitting layer, a hole transport layer, a hole injection layer, a positive electrode such as an indium tin oxide film (ITO film: transparent conductive film), and the like are stacked in the light emitting element, although not illustrated. In the present embodiment, as illustrated in FIG. 2, the light emitting elements constituting each layer of the ELD 2 are vapor-deposited on the front surface (upper surface) side of the substrate 5 to form an EL main body portion 21 (hereinafter, sometimes referred to as “main body portion 21”). For materials of each layer, various organic substances such as diamine, anthracene, a metal complex, and the like can be used. Note that these light emitting elements include various driving means (not illustrated) different depending on a driving system for the negative electrode and the positive electrode. The driving means of the present embodiment is configured to be driven and controlled by the DDIC 4, and hereinafter, the light emitting element and the driving means described above may be collectively referred to as the main body portion 21.

The ELD 2 includes the main body portion 21 in which a large number of light emitting elements constituting pixels (pixels: pixels) are integrated, and a glass 6 (hereinafter, referred to as “cover glass 6”) functioning as a cover for sealing the main body portion 21. The cover glass 6 transmits light from the main body portion 21 that emits light, thereby allowing an image or the like formed by the main body portion 21 to be visually recognized from the outside.

In the EL main body portion 21, although not illustrated, electrons and holes injected in the electron injection layer and the hole injection layer pass through the electron transport layer and the hole transport layer, respectively, and are bound in the light emitting layer, thereby generating binding energy at an atomic level. The electrons in the light emitting layer are excited by the energy at this time. When the excited electron returns from the excited state to the ground state of the lowest level which is energetically stable, light (photon) is generated by the energy of the level difference and emitted. In order to utilize this light emission phenomenon, the light emitting element of each pixel is individually driven and controlled by the DDIC 4, and the light from each pixel formed by the light emission phenomenon is transmitted through the cover glass 6 and displayed to the outside, so that the light can be formed and visually recognized as an image.

In the FPC 3, a connection terminal of a terminal portion (not illustrated) is joined and integrated with a part of a printed wire 51 (formed by aluminum (Al) in the present embodiment) (referred to as connection terminal 52: see FIG. 2) provided on the substrate 5.

Note that, although the joining between the FPC 3 and the substrate 5 requires some thermal conditions in, for example, the embodiment of the present disclosure, joining and conduction may be performed using an anisotropic conductive film (hereinafter, referred to as “ACF”) or an anisotropic conductive paste (hereinafter referred to as “ACP”) that enables joining without a high temperature as in solder or the like. However, in the case of joining and connection by the ACF or the ACP, there is a risk that the resistance value at a connection portion increases.

Therefore, in a case where avoidance of such risk is desired, for example, although the work is performed at room temperature, joining integration by ultrasonic vibration involving pressurization may be performed to achieve electrical connection and conduction. In the case of joining integration by the ultrasonic vibration, in order to ensure the joining, for example, if a pad electrode in which aluminum is deposited (or stacked) in a thick shape is formed on the connection terminal 52 on the substrate 5 side (or a bump is formed by aluminum), and then joining is performed using this thick pad electrode (or bump) including aluminum, it is convenient since the joining state becomes more reliable. However, in a case of a structure in which the wiring density of the FPC to be connected is high, in joining via a thick pad electrode or bump, it is conceivable that a trouble such as a short circuit occurs due to wiring contact between adjacent wires, and it may be difficult in some cases to perform joining with high density by this ultrasonic vibration. Therefore, in such a case, it is preferable to avoid a thick pad electrode or bump. Note that a specific method of forming the aluminum pad electrode in a thick shape or the like will be described later.

As described above, in the FPC 3 according to the embodiment of the present disclosure, it is possible to perform pressure-joining connection by ultrasonic vibration involving pressurization at room temperature, or connection by the ACF or the ACP involving some thermal action. In particular, in a case where connection is performed using the ACF or the ACP, for example, when silicon (Si), silicon nitride (SiC), and the like is used as a material constituting the substrate 5, a certain degree of heat absorption action can be expected. Furthermore, in a case where it is necessary, for example, an appropriate material rich in thermal absorption may be separately attached to the lower surface of the substrate 5 or the like.

Furthermore, in a case where such connection by ultrasonic vibration or connection by the ACF or the ACP is not preferable or difficult, it may be difficult in some cases to realize the connection depending on a physical size, for example, in addition to these conduction methods. However, female and male connectors may be provided in the FPC 3 and the substrate 5, respectively, and these connectors may be mechanically connected to each other to conduct the connection.

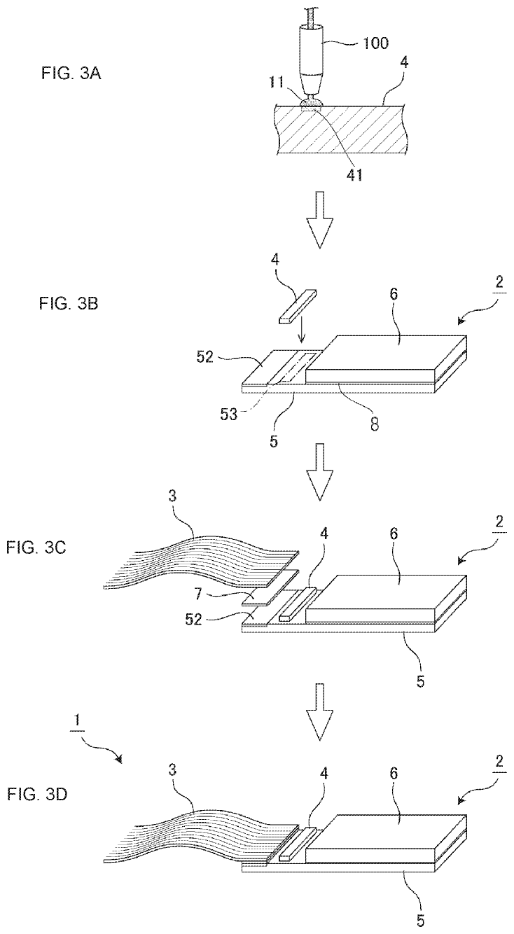

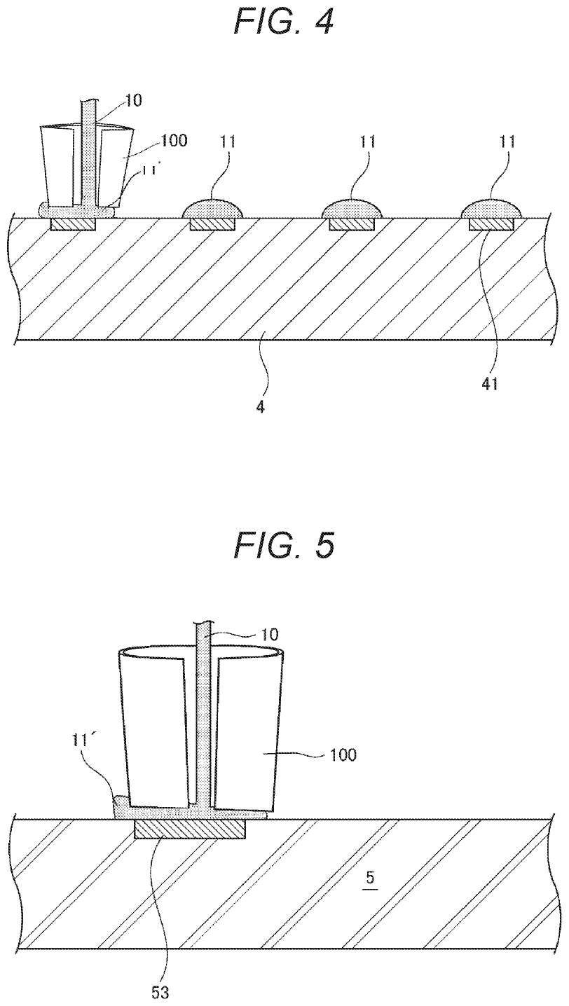

In the embodiment of the present disclosure, as illustrated in FIG. 2, the DDIC 4 is joined and electrically connected to the substrate 5 side by ultrasonic joining at room temperature. For this connection, the DDIC 4 is provided with a pad electrode 41 including aluminum (Al) (hereinafter, sometimes referred to as “aluminum pad electrode 41”) on one surface side (the lower surface in FIGS. 2 and 3). In addition, the aluminum pad electrode 41 is provided with a bump including aluminum (Al-bump: hereinafter, sometimes referred to as “aluminum bump 11”) denoted by reference numeral 11 in FIG. 4. Note that, although details will be described later, the operation of forming the aluminum bump 11 on the DDIC 4 in the state before connection with the substrate 5, in other words, in the state of a single unit separated from the substrate 5 is performed in a state where the DDIC 4 is upside down for the convenience of the operation, as illustrated in FIG. 4, unlike in FIGS. 2 and 3.

Note that the material for forming the pad electrode 41 may be a good conductor such as copper (Cu), gold (Au), silver (Ag), and the like, for example. However, in consideration of physical properties, a material including aluminum (Al), which is the same metal as the aluminum bump, is preferable for connection. The aluminum bump 11 on the DDIC 4 side and an Al pad electrode 53 (hereinafter, sometimes referred to as “aluminum pad electrode 53”) on the substrate 5 side are joined and electrically connected by the above-described ultrasonic joining at room temperature.

In the present embodiment, the aluminum bump 11 is formed on the DDIC 4 side via the aluminum pad electrode 41. However, the present disclosure may adopt a joining structure in which a similar aluminum bump is formed on the aluminum pad electrode 53 A on the substrate 5 side and the aluminum bumps are joined to each other. Note that a method of forming the aluminum bump 11 on the substrate 5 side will be described later with reference to FIG. 5.

In the substrate 5, the ELD 2 is fixed to the upper surface of the substrate 5 with an appropriate adhesive 8. The ELD 2 is formed by stacking the EL main body portion 21 in multiple layers by vapor deposition or the like on one surface side (upper surface in FIG. 2) of the substrate 5, and required power corresponding to information to be displayed as an image or the like is supplied from a feeder line (not illustrated) to each of positive and negative electrodes provided for each pixel through the DDIC 4. As a result, in the ELD 2, in FIG. 2, light of colors of various wavelengths emitted from the main body portion 21 is emitted from the cover glass 6 to the outside, so that image information is displayed toward the outside.

Furthermore, as illustrated in FIG. 2, the substrate 5 is provided with a printed wire 51 having a predetermined wiring pattern shape formed in a foil film shape by, for example, sputtering, etching, or the like using a material such as aluminum (Al) (copper (Cu) or the like) on the upper surface 5A side (and the inside or the like) which is a portion where the ELD 2 is formed. Then, the printed wire 51 and the DDIC 4, and the printed wire 51 and an electrode or a connection terminal (not illustrated) of the ELD 2 are electrically connected. As a result, a control signal line of each light emitting element constituting the pixel of the ELD 2 is constituted. Note that, in consideration of the fact that the ELD 2 is vulnerable to thermal action, as described above, it is preferable to avoid the use of solder, flux, and the like and conduct the ELD 2 by ultrasonic joining or the like involving pressurization at room temperature.

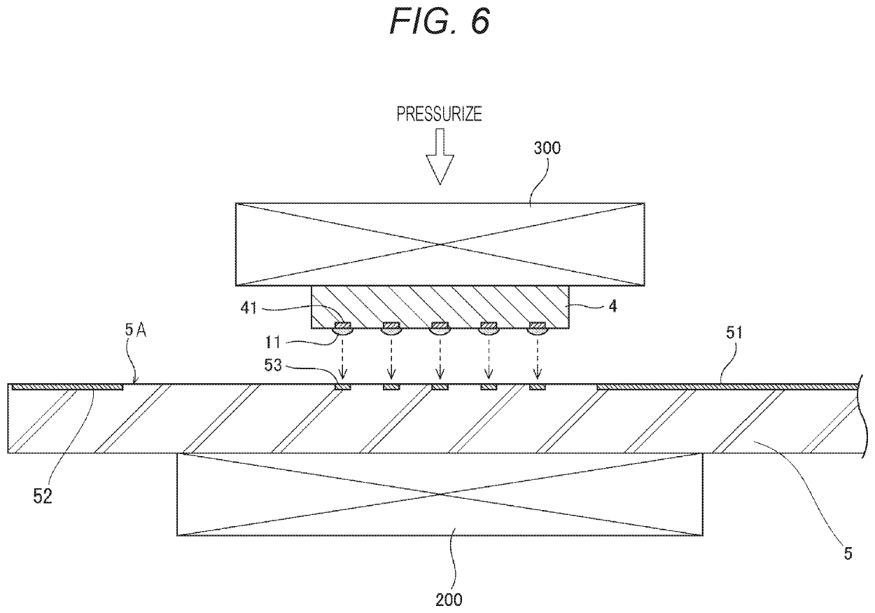

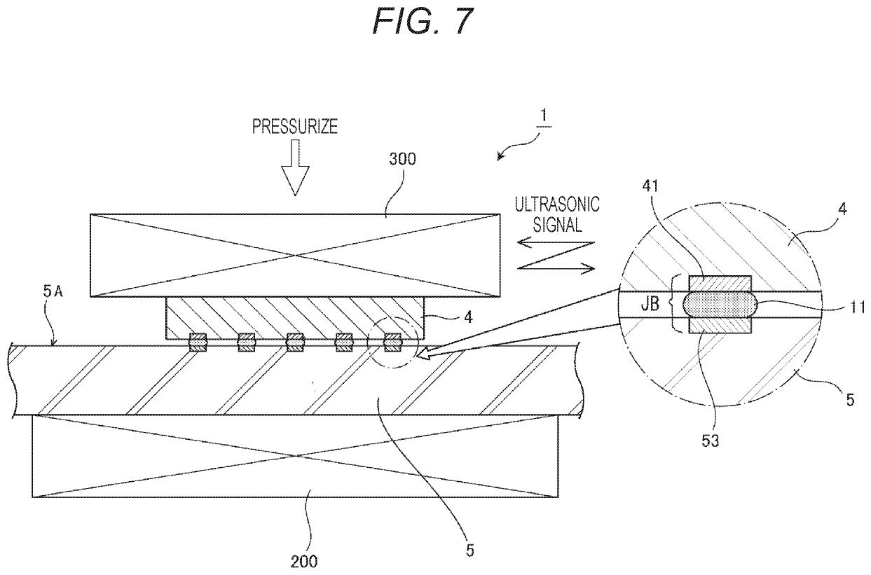

An aluminum pad electrode 53 similar to the aluminum pad electrode 41 of the DDIC 4 is formed at a predetermined portion of one surface (upper surface 5A in FIG. 2) of the substrate 5 which is a joined area of the DDIC 4 with the aluminum pad electrode 41. As a result, as illustrated in FIGS. 6 and 7, these both aluminum pad electrodes 41 and 53 are joined and integrated via an aluminum bump 11 to be described later (hereinafter, this joined-integrated portion may be referred to as “joined body JB”). The joined body JB is constituted by being joined and integrated by ultrasonic vibration involving pressurization at room temperature described later. Note that, for the joined body JB, since joining between the same kind of metals has better joining stability, the aluminum pad electrode 53 of the substrate 5 is also preferably formed by aluminum (Al).

### [Method of Manufacturing Semiconductor Device]

Next, a method (process) for manufacturing a semiconductor device provided with the organic EL display device according to the present embodiment will be described with reference to FIG. 3 and other drawings as necessary.

1) On the surface 5A side of the substrate 5 formed by stacking the main body portion 21 of the ELD 2 together with the printed wire 51 in a multilayer state in a predetermined pattern by vapor deposition or the like, the cover glass 6 is first fixed and attached with the appropriate adhesive 8 (see FIG. 3B). That is, the cover glass 6 is fixed and attached to the main body portion 21 of the ELD 2 provided on the upper surface (surface 2A) side of the substrate 5. Note that, in the case of the present embodiment, the electrical connection between the terminal side (not illustrated) of the main body portion 21 and the printed wire 51 on the substrate 5 side is made when the printed wire 51 is formed and/or when the main body portion 21 is formed by vapor deposition.

2) Next, the DDIC 4 is implemented on the substrate 5. Before the DDIC 4 is implemented on the substrate 5, as illustrated in FIG. 3A, the aluminum bump 11 is formed on the DDIC 4 in advance in a state of a single component (hereinafter referred to as “single unit”) before the implementation. That is, as illustrated in FIG. 4, the aluminum bump 11 is formed in a stacked state in advance on the lower surface (in FIGS. 3 and 4, since the DDIC 4 is turned upside down, the upper surface) of the aluminum pad electrode 41. Note that this specific forming method will be described in detail later.

3) The DDIC 4 in the upside down state is then vertically inverted as illustrated in FIG. 2. Then, the aluminum bump 11 formed on the DDIC 4 in step 2) and the aluminum pad electrode 53 on the substrate 5 side are aligned with high accuracy (see FIG. 3B). Thereafter, the DDIC 4 and the substrate 5 are joined by a joining method using pressurization and ultrasonic vibration without heating using an ultrasonic joining tool 300 or the like described later illustrated in FIG. 6. Note that the substrate 5 here is firmly fixed and held on a stage 200.

4) Thereafter, using an anisotropic conductive film (ACF) 7 (see FIG. 3C), the FPC 3 is subjected to ACF implementation on the printed wire 51 on the substrate 5 to electrically connect the substrate 5 and the FPC 3 (see FIG. 3D).

5) Finally, the surfaces or the like of the FPC 3, the DDIC 4, and the substrate 5 are insulated and coated with an appropriate coating material such as an under fill (UF), for example, an ultraviolet curable resin.

### (1-2. Joining Method in Organic EL Display Device)

In the present embodiment, as described above, the aluminum bump 11 is formed on the DDIC 4 in advance for electrical joining between the DDIC 4 and the substrate 5 side. However, in the present disclosure, the aluminum bump 11 may not be provided on the aluminum pad electrode 41 on the DDCI 4 side, but may be formed on the aluminum pad electrode 53 on the substrate 5 side, or may be formed on both the aluminum pad electrode 41 and the aluminum pad electrode 53.

### [Method of Forming Aluminum Bump]

As for the method of forming the aluminum bump, for example, in the case of forming the aluminum bump on the DDIC 4, as illustrated in FIG. 4, prior to this work, the DDIC 4, which is a single unit, is first turned upside down. That is, the aluminum pad electrode 41 (the aluminum pad electrode 41 may include, for example, copper (Cu), gold (Au), and the like as long as it is a conductor, but preferably includes aluminum (Al) which is the same metal as the aluminum bump 11) constituting a part of the wiring portion provided on the lower surface is arranged upward.

Then, for the aluminum pad electrode 41, the aluminum bump 11 is formed by an aluminum (Al) wire 10 by a wire bonder 100 (reference numeral 11′ in FIG. 4 denotes a state in the process of forming the aluminum bump 11). Furthermore, the shape of the aluminum bump formed using the aluminum wire (Al wire) 10 is different from, for example, a bump using solder, and since a ball shape cannot be formed, the aluminum bump is formed in a wedge shape, but there is no particular problem with this shape at the time of joining. Furthermore, the aluminum bump 11 may be formed by performing ultrasonic joining or the like without heat.

Note that, although the wire bonder 100 of the present embodiment can be joined not only with the same metal but also with different kinds of metals, it is preferable to use the same metal from the viewpoint of joining stability as described above.

Note that the formation of the aluminum bump on the DDIC 4 here is work before the DDIC 4 is joined to the substrate 5 as described above, and thus does not cause a thermal influence on the ELD 2 that is weak against heat.

On the other hand, the method of forming the aluminum bump on the substrate 5 side may also be a method using the wire bonder 100 or other means as illustrated in FIG. 5 as long as a certain thermal condition is allowed in this formation.

[Joining Method with CoC Using Aluminum Bump]

Next, an example of joining the aluminum bump 11 and the aluminum pad electrodes 41 and 53 will be described with reference to FIGS. 6 and 7. In the CoC (Chip on Chip) joining structure using the aluminum bump according to the present embodiment, the aluminum pad electrode 41 on the DDIC 4 side is joined to the aluminum pad electrode (which may be an aluminum bump) 53 on the substrate 5 side via the aluminum bump 11. Hereinafter, this joining method will be described.

1) As described above, for the DDIC 4, the aluminum bump 11 is previously formed on the aluminum pad electrode 41 in a state of the single component (single unit) as illustrated in FIG. 4 before the DDIC 4 is joined to the substrate 5. On the other hand, with respect to the substrate 5, the aluminum pad electrode 53 is formed by precisely aligning the substrate 5 with a portion of the DDIC 4 corresponding to the aluminum pad electrode 41 (note that the pad electrode 53 may be formed as a part of the printed wire 51 or at the same timing as the manufacture thereof at the time of manufacture by sputtering or the like so as to be connected to the pattern wire).

2) Next, for room-temperature joining, as a vibration pressurizing jig or apparatus, the stage 200 constituting an anvil (pedestal) and the ultrasonic joining tool 300 (hereinafter, abbreviated as “tool 300”) constituting a horn including iron or the like disposed immediately above and oppositely to the stage are prepared. Then, the vicinity of the pad electrode 61 on the substrate 5 side is mounted on the stage 200, and the upper surface of the DDIC 4 is adsorbed and held by an adsorption chuck (not illustrated) or the like provided on the lower surface of the tool 300.

3) Then, the positions of the tool 300 and the stage 200 (alternatively, at least one of the tool 300 and the stage 200) are finely adjusted. That is, as illustrated in FIG. 6, the aluminum pad electrode 53 to be joined on the substrate 5 side and the aluminum pad electrode 41 on the DDIC 4 side and the Al bump 11 formed on the lower surface thereof are precisely aligned so as to be accurately matched with each other in a precise state.

4) Thereafter, the tool 300 is pressed to bring the aluminum pad electrode 41 on the DDIC 4 side into contact with the aluminum pad electrode 53 on the substrate 5 side via the aluminum bump 11 (see FIG. 7). Then, the tool 300 or the like is operated at room temperature (for example, 30° C. or lower) to perform ultrasonic vibration involving pressurization. That is, by applying a required load downward to the tool 300, the aluminum pad electrode 41 and the Al bump 11 are pressurized toward the aluminum pad electrode 53 on the substrate 5 side, and the tool 300 is ultrasonically vibrated in the pressurized state. As a specific joining condition using ultrasonic vibration on the tool 300 side, for example, a load of 78 N (Newton), a vibration frequency of 50 KHz, an amplitude of 1.79 μm, and the like are possible. Note that the operating time (m seconds) may be any time as long as a certain joining strength can be obtained.

By joining with the tool 300 or the like, the aluminum pad electrode 53 on the DDIC 4 side can be firmly joined to the aluminum pad electrode 41 on the substrate 5 side. Furthermore, the ultrasonic vibration causes vibration in a direction parallel to the joining surface. Note that, at the time of this joining work, the ELD 2 is already mounted on the substrate 5, but there is no problem since the joining is performed at room temperature. Furthermore, the joining conditions in the present embodiment are not particularly limited to the above-described conditions, and it is sufficient that a required joining strength can be obtained.

5) As a result, even if an oxide film or the like is formed on an Al surface, the oxide film or the like is removed by ultrasonic vibration, and Al can be reliably joined to each other.

### [Function and Effect]

Therefore, according to the embodiment of the present disclosure, the joining by CoC (Chip on Chip), that is, the joining between the DDIC 4 and the substrate 5 on which the main body portion 21 of the organic EL display device 2 is formed is performed by pressurization at room temperature without heat and ultrasonic vibration using the stage 200 and the tool 300. In this joining by ultrasonic vibration, in a case where aluminum, for example, is used as a material to be used, even if an oxide film is formed on the surface of aluminum, for example, the oxide film is removed by rubbing both joining surfaces against each other by ultrasonic vibration, so that it is possible to perform firm joining without causing joining failure. As a result, room-temperature joining with CoC, that is, the DDIC 4 can be joined and connected onto the substrate 5 by pressurization and ultrasonic waves without being heated.

Furthermore, according to the joining method according to the embodiment of the present disclosure, the joining work at this time is work at room temperature that does not require heating or the like as described above. Therefore, even in the substrate 5 on which the ELD 2 weak to heat is formed, the CoC joining work can be performed, which is convenient.

Therefore, according to the embodiment of the present disclosure, when the aluminum bump 11 is provided in the DDIC 4, prior to joining to the aluminum pad electrode 53 on the substrate 5 side, the single DDIC 4 is turned upside down to form the aluminum bump, so that the work can be easily performed and the work can be performed reliably and quickly.

Furthermore, in the case of performing work at room temperature by ultrasonic vibration in the case of joining the DDIC 4 to the substrate 5, even if the main body portion 21 of the ELD 2 is already formed on the substrate 5, there is no risk that a thermal influence will spread to the ELD 2, which is particularly convenient.

In addition, as in the embodiment according to the present disclosure, in a joining structure in which pad electrodes including the same metal such as aluminum or the like are connected to each other, or bumps including the same metal such as aluminum are connected to each other, or a pad electrode including the same metal such as aluminum and a bump are connected to each other, stability with respect to a joining surface and a joining phase is favorable, leading to improvement of reliability for a semiconductor device or the like having these joining structures.

In addition, as in the embodiment of the present disclosure, in a semiconductor device or the like manufactured with a joining structure by ultrasonic vibration involving pressurization at room temperature, occurrence of a warpage phenomenon or the like of a substrate or the like due to heat can also be prevented, so that the yield can also be improved.

Furthermore, as in the embodiment of the present disclosure, in a semiconductor device or the like using a joining structure using ultrasonic vibration, since an insulating resin or the like is not interposed in a joining portion, a resistance value at the joining portion does not increase as compared with a joining structure using the ACF, the ACP, and the like, for example, and thus, it is possible to lead to an increase in operation speed of the device itself.

### 2. Modification of Embodiment

Next, a modification of the above-described embodiment will be described. Note that, in the modification, the same portions as those in the above-described embodiment are denoted by the same reference numerals, and a redundant description is avoided.

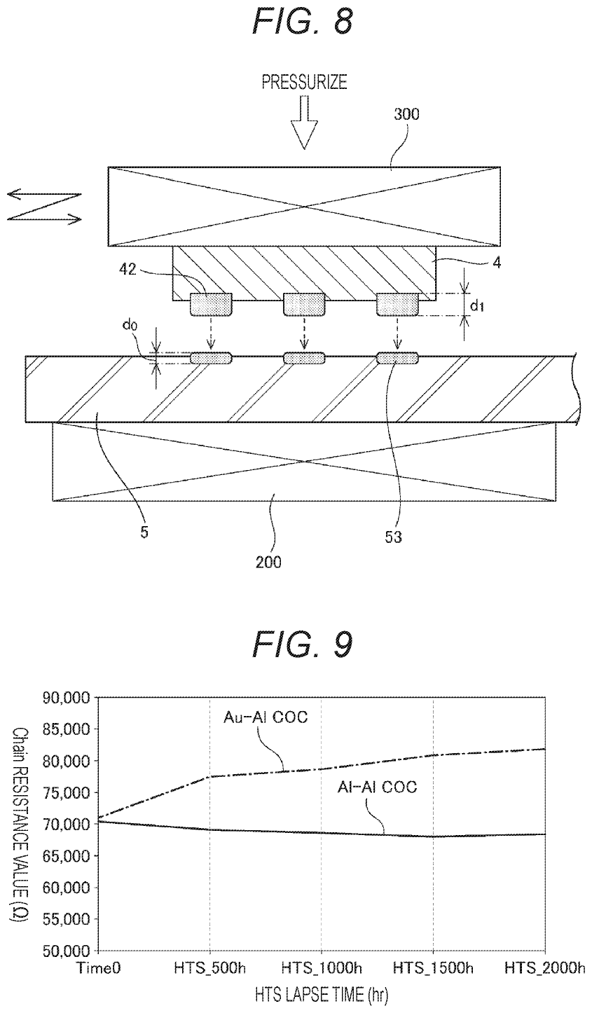

FIG. 8 illustrates a modification of the above embodiment according to the present disclosure. In this modification, in order to stably join the aluminum pad electrode 53 on the substrate 5 side and the aluminum pad electrode (not illustrated) of the DDIC 4, the aluminum pad electrode on the DDIC 4 side is not provided with an aluminum bump, and a thick aluminum pad electrode 42 is formed as an alternative means.

### [Configuration]

Usually, for example, in the case of a structure or the like in which a film is formed by sputtering to form a pad electrode, the aluminum pad electrode 53 on the substrate 5 side has a thickness of about 0.5 to 1 μm (which is defined as a thickness d₀), for example. On the other hand, the thick aluminum pad electrode 42 (which is hereinafter referred to as aluminum pad thick electrode 42) on the DDIC 4 side has a thickness of, for example, about 8 μm (which is defined as a thickness d1, that is, d₁>>d₀).

### [Method of Forming Thick Pad Electrode]

As a method of forming the aluminum pad thick electrode 42, for example, if the following method is possible, the aluminum pad thick electrode may be formed by this method. That is,
1) First, a pattern wiring portion is formed by aluminum having a normal thin film thickness.
2) Thereafter, in the pattern wiring portion, masking using a material is appropriately performed particularly on an area other than the area where the pad thickness electrode is desired to be formed.
3) Then, an aluminum film is further formed on the pattern wiring portion by sputtering or the like using aluminum of the same material.
4) Finally, a mask is removed to obtain an aluminum pad thick electrode.

Furthermore, in addition to this method, as a method of forming the aluminum pad thick electrode, for example, the aluminum pad thick electrode may be formed by a method such as aluminum plating, aluminum vapor deposition, and the like on a terminal on which the aluminum pad thick electrode is to be formed among terminals in which a film is formed by aluminum on a wafer. In short, the aluminum pad thick electrode may be formed by any forming method as long as the aluminum pad thick electrode having a required film thickness is formed.

In addition, the method of forming the aluminum pad thick electrode 42 is not particularly limited to the method described above. There is no particular limitation as long as the method makes formation easy, uses the aluminum material same as that of the aluminum pad electrode 53 on the substrate 5 side, and enables reliable and stable joining by ultrasonic vibration at room temperature involving pressurization.

### [Function and Effect]

According to the modification of the present disclosure, the aluminum pad thick electrode 42 on the DDIC 4 side and the aluminum pad electrode 53 having a normal thickness on the substrate 5 side can be joined by ultrasonic vibration at room temperature involving pressurization using the similar stage 200 and the tool 300 as in the above embodiment. That is, according to the present modification, unlike the above-described embodiment, it is not necessary to perform work of stacking the aluminum bump 11 on the pad electrode by a wire bonder or the like.

### 3. Experimental Example

### [Experimental Example Regarding Temporal Change in Resistance Value]

In addition, the inventors of the present disclosure conducted a comparative experiment regarding a secular (temporal) change in a resistance value of a gold-aluminum (Au—Al) joined body and an aluminum-aluminum (Al—Al) joined body.

As a result, the graph illustrated in FIG. 9 was obtained. According to this graph, it was found that the resistance value of the joined body of gold and aluminum (Au—Al) after a lapse of 2000 hours was increased by about 18% as compared with the initial resistance value.

On the other hand, it was found that the resistance value of the joined body of aluminum and aluminum (Al—Al) did not increase even after the lapse of 2000 hours which is the same lapse time as described above although the detailed qualitative and theoretical reasons were unknown. As a result, it was found that a joined body of aluminum and aluminum can realize a high-quality connection state over a long period of time as compared with a joined body of gold and aluminum (Au—Al).

### 4. Application Examples

As described above, in the embodiments according to the present disclosure, the organic EL display device which is an example of the CoC joining structure has been described, but the present disclosure is also suitable for application to, for example, a liquid crystal display device which is weak against heat.

Furthermore, the present disclosure can be applied to, for example, instrument display devices provided at a driver seat in transportation means such as automobiles, aircrafts, railways, ships, submarines, and the like, instrument panels in artificial satellites or the like, monitor display devices in various medical devices including electronic endoscopes or the like at medical sites, monitor display devices for consumer or military images, image display devices in various mobile terminal devices including mobile phones, radiation measurement monitor display devices in nuclear facility apparatuses such as nuclear reactors, nuclear fusion reactors, and the like, display devices for counter measurement of cosmic rays, particles, and the like in high energy experimental facilities such as accelerators, and other various applications and fields.

Although the present disclosure has been specifically described above with reference to the embodiments, the present disclosure is not limited to the above-described embodiments, and various modifications can be made. For example, in the above embodiment, an example in which the aluminum bump is formed on the aluminum pad electrode of the DDIC constituting a second semiconductor (second chip) has been described, but the present technology is not limited thereto. That is, in the present disclosure, as described above, an aluminum bump may be formed only on the aluminum pad electrode of the substrate 5, which is a first semiconductor to be joined to the DDIC 4, which is the second semiconductor. Alternatively, there may be provided a structure in which an aluminum bump is formed on both pad electrodes and both the aluminum bumps are joined to each other at room temperature by ultrasonic vibration involving pressurization.

In addition, in the present disclosure, the pad electrode and the bump as described above are formed using aluminum as a material, but the formation material is not limited thereto, and any material having good electrical conductivity, such as copper (Cu), gold (Au), silver (Ag), and others, for example, can be used, and a similar effect can be obtained. In addition, the materials to be used may be subject to limitations because metals with good electrical conductivity other than the above and high hardness may not necessarily be suitable for joining by ultrasonic vibration involving pressurization.

The embodiments and each configuration example according to the present disclosure have been described above. Finally, the description of the above-described embodiments and the configuration examples is an example of the present disclosure, and the present disclosure is not limited to the above-described embodiments and the configuration examples. For this reason, it is needless to say that various modifications other than the above-described embodiments and the configuration examples can be made according to the design and the like without departing from the technical idea according to the present disclosure. Furthermore, the effects described in this specification are illustrative only and are not limitative. Furthermore, there may be other effects.

Note that, the drawings in the above-described embodiments and each configuration example are schematic, and dimensional ratios (aspect ratios) and the like of the individual portions do not always coincide with actual ones. Furthermore, it is needless to say that the drawings include parts having different dimensional relationships and ratios. In addition, various modes can be applied as long as effects similar to the effects described in the above-described embodiments and configuration examples can be obtained.

Note that the present disclosure can have the following configurations. With such configurations, it is possible to realize a flip connection structure, a room-temperature flip connection structure, and a connection method therefor, which do not cause a risk of deterioration of a substrate or a semiconductor chip due to heat.

(1) A flip-chip connection structure in which semiconductors are connected by a flip chip, the flip-chip connection structure including:
terminals that connects the semiconductors, the terminals each being formed by aluminum (Al),
the terminals being integrally joined to each other to constitute a joined body.

(2) The flip-chip connection structure according to (1) above, in which
the joined body includes either of:
a configuration in which one of the semiconductors is formed by an aluminum bump and another one of the semiconductors is formed by an aluminum pad electrode, or
a configuration in which the both of the semiconductors are formed by the aluminum bump.

(3) The flip-chip connection structure according to (2) above, in which
the aluminum bump includes either of:
an aluminum bump formed by a wire bonder using an aluminum wire, or
an aluminum bump formed in a wedge shape by being joined onto a pad electrode at room temperature using the aluminum wire.

(4) The flip-chip connection structure according to (2) or (3) above, in which
the aluminum pad electrode includes either of:
an aluminum pad electrode having a configuration in which a pad electrode is grown in a thickness direction of the pad electrode by an aluminum wire, or
an aluminum pad electrode having a configuration in which a pad electrode having a thick film shape is formed by sputtering or vapor deposition during manufacturing of a wafer.

(5) A room-temperature flip-chip connection structure of a flip chip in which a semiconductor is connected to a substrate to be used in a liquid crystal panel or an organic EL panel of a display system, in which
the semiconductor is joined and formed to a substrate of at least one of the liquid crystal panel and the organic EL panel at room temperature.

(6) The room-temperature flip-chip connection structure according to (5) above, in which
joining at the room temperature is performed by functions of an ultrasonic wave and pressurizing force.

(7) The room-temperature flip-chip connection structure according to (5) above, in which
the substrate includes a substrate of a stacked display-based panel, and
the semiconductor is joined to the substrate at room temperature.

(8) A flip-chip connection method of forming semiconductors by joining the semiconductors to each other by a flip-chip connection method using a joined body joined by an aluminum bump and an aluminum pad electrode or an aluminum bump and an aluminum bump, the flip-chip connection method including:
when joining of a flip chip is performed, joining by weighting or pressurization and an ultrasonic wave in an environment of room temperature in any step.

### REFERENCE SIGNS LIST

1 Semiconductor device
2 Organic EL display device (ELD)
21 EL main body portion
3 Flexible printed circuit (FPC)
4 Display drive IC (DDIC)
41 Pad electrode (aluminum pad electrode)
42 Thick aluminum pad electrode (aluminum pad thick electrode)
5 Organic EL display substrate (substrate)
51 Printed wire
52 Terminal electrode
53 Aluminum pad electrode
6 Cover glass (screen)
7 Anisotropic conductive film 7 (ACF)
10 Aluminum (Al) wire
11 Aluminum bump
11′ State in process of forming aluminum bump
100 Wire bonder
200 Stage
300 Tool
JB Joined body

1. A flip-chip connection structure in which semiconductors are connected by a flip chip, the flip-chip connection structure comprising:
terminals that connects the semiconductors, the terminals each being formed by aluminum (Al),
the terminals being integrally joined to each other to constitute a joined body.

2. The flip-chip connection structure according to claim 1, wherein
the joined body includes either of:
a configuration in which one of the semiconductors is formed by an aluminum bump and another one of the semiconductors is formed by an aluminum pad electrode, or
a configuration in which both of the semiconductors are formed by the aluminum bump.

3. The flip-chip connection structure according to claim 2, wherein
the aluminum bump includes either of:
an aluminum bump formed by a wire bonder using an aluminum wire, or
an aluminum bump formed in a wedge shape by being joined onto a pad electrode at room temperature using the aluminum wire.

4. The flip-chip connection structure according to claim 2, wherein
the aluminum pad electrode includes either of:
an aluminum pad electrode having a configuration in which a pad electrode is grown in a thickness direction of the pad electrode by an aluminum wire, or
an aluminum pad electrode having a configuration in which a pad electrode having a thick film shape is formed by sputtering or vapor deposition during manufacturing of a wafer.

5. A room-temperature flip-chip connection structure of a flip chip in which a semiconductor is connected to a substrate to be used in a liquid crystal panel or an organic EL panel of a display system, wherein
the semiconductor is joined and formed to a substrate of at least one of the liquid crystal panel and the organic EL panel at room temperature.

6. The room-temperature flip-chip connection structure according to claim 5, wherein
joining at the room temperature is performed by functions of an ultrasonic wave and pressurizing force.

7. The room-temperature flip-chip connection structure according to claim 5, wherein
the substrate includes a substrate of a stacked display-based panel, and
the semiconductor is joined to the substrate at room temperature.

8. A flip-chip connection method of forming semiconductors by joining the semiconductors to each other by a flip-chip connection method using a joined body joined by an aluminum bump and an aluminum pad electrode or an aluminum bump and an aluminum bump, the flip-chip connection method comprising:
when joining of a flip chip is performed, joining by weighting or pressurization and an ultrasonic wave in an environment of room temperature in any step.
